(19) United States
(12) Patent Application Publication
(10) Pub. No.: US 2020/0072872 A1
(43) Pub. Date: Mar. 5, 2020

(54) CURRENT SENSING MODULE FOR CURRENT SENSOR AND METHOD FOR MANUFACTURING CURRENT SENSING MODULE

(71) Applicant: FLEX INSTRUMENTS CO., LTD., New Taipei City (TW)

(72) Inventor: Win-Throng CHEN, New Taipei City (TW)

(21) Appl. No.: 16/122,479

(22) Filed: Sep. 5, 2018

(51) Int. Cl. G01R 1/22; G01R 1/02; H01F 38/20; G01R 15/12; G01R 15/18

(52) U.S. Cl. CPC G01R 1/22; G01R 1/02; G01R 15/18; G01R 15/12; H01F 38/20

(57) ABSTRACT

The present invention provides a current sensing module for a current sensor and a method for manufacturing the current sensing module. The current sensing module includes a spacer layer including a through hole and being annular in shape, and a circuit board electrically connected to the current sensor and includes at least two structural layers. The two structural layers cover the spacer layer and each of the structural layers includes at least one metal wire layer insulated from the spacer layer. The two metal wire layers are conducted to form a loop coil surrounding the spacer layer. When a wire is located in the through hole, an external power supply power to the circuit board, such that the circuit board has a detection state in which a sensing current is outputted due to magnetic induction generated by the loop coil during the wire is electrically conducted.

### FIELD OF THE INVENTION

The present invention relates to a current sensing module and a method for manufacturing the current sensing module, and particularly to a current sensing module for a current sensor and a method for manufacturing the current sensing module.

### BACKGROUND OF THE INVENTION

Conventional current sensors mostly adopt the form of a clamp meter, and a wire is inserted into the clamp meter to detect an alternating current flowing in the wire.

Current commercially available current sensors are roughly divided into four categories. A current sensor of the first category is for measuring a supply current value of a power supply system, and is applied to such as electricity companies, buildings and households, with a measurement range approximately between 0.1 A to 1000 A. A current sensor of the second category is for measuring a large alternating current value of a supply system, and is applied to electricity companies and buildings, with a measurement range reaching as high as several thousand amps, wherein the method for measuring an extremely large alternating current value is performed by using a Rocowsky coil. A current sensor of the third category is for measuring leakage alternating current of power supply systems and leakage alternating current of electrical appliances, with a measurement range approximately between 10 μA and 100 A. A current sensor of the fourth category is for measuring direct current signals transmitted between interfaces of industrial controllers, with a measurement range approximately between 20 mA to 4 mA and a resolution of 1 μA.

A current clamp current sensor, for example, “Clamp Jaw Assembly” disclosed by the U.S. Pat. No. 8,159,211, includes a first clamp jaw and a second clamp jaw. The first clamp jaw comprises therein a first jaw clamp core and a first non-conductive shield, and the second clamp jaw comprises therein a second jaw clamp core and a second non-conductive shield. The first clamp jaw further comprises therein a flexible printed circuit board (PCB) so as to use the flexible PCB to detect conductive properties of the first clamp jaw and the second clamp jaw.

For another example, the U.S. Pat. No. 8,914,249 discloses “Resistance Measuring Apparatus”, including a clamp sensor. The clamp sensor includes an injection clamp unit and a detection clamp unit. Each of the injection clamp unit and the detection n clamp unit includes arc-shaped core, a bobbin installed outside the arc-shaped core and a coil wound around the bobbin. The injection clamp unit and the detection clamp unit are enclosed in a housing.

Further, the U.S. Pat. No. 6,191,673 discloses “Current Transformer”, including two transformer units. Each of the transformer units includes an iron core and a secondary winding wound outside the iron core, and a shield winding is further wound outside the transformer units.

In the above patents, the clamp meter is primarily formed by winding a coil around a magnetic component, such that a current value of the wire is measured through the magnetic component and the coil when the wire is located at the clamp meter. Most conventional coils are accomplished through winding copper wires. Further, to mutually separate the coil from the magnetic component, different spaces for respectively accommodating the coil and the magnetic component are usually formed in the clamp meter. Thus, the overall volume of the clamp meter is enlarged and material costs of materials used are also increased.

### SUMMARY OF THE INVENTION

In view of the above, it is a primary object of the present invention to provide a current sensing module for a current sensor and a method for manufacturing the current sensing module.

According to the above object, the present invention provides a current sensing module for a current sensor. The current sensing module includes at least one spacer layer and at least one circuit board. The spacer layer is annular in shaped, and includes a through hole at a center thereof for a wire to pass through. The circuit board is electrically connected to a current sensor, and includes at least of two structural layers for covering the spacer layer. Each of the structural layers includes an insulation layer, and a metal wire layer provided on the insulation layer and mutually insulated from the spacer layer. The two metal wire layers are mutually electrically to form at least one loop coil, which surrounds the spacer layer. When the wire is located in the through hole and electrically conducted, the circuit board has a detection state in which the circuit board a sensing current is outputted due to magnetic induction generated by the loop coil.

In one embodiment, the current sensing module further includes a magnetic separation layer for covering the external of the circuit board.

In one embodiment, the circuit board further includes four of the structural layers, which are a first structural layer, a second structural layer opposite the first structural layer, a third structural layer located between the first structural layer and the second structural layer, and a fourth structural layer located between the third structural layer and the second structural layer. The spacer layer is located between the third structural layer and the fourth structural layer.

In one embodiment, the spacer layer is selected from a group consisted of a magnetic material and a non-magnetic material.

In one embodiment, the spacer layer is insulated from the first structural layer and the second structural layer.

In one embodiment, the first structural layer includes thereon a first metal wire layer, the second structural layer includes thereon a second metal wire layer mutually electrically connected to the first metal wire layer, the third structural layer includes thereon a third metal wire layer, and the fourth structural layer includes thereon a fourth metal wire layer mutually electrically connected to the third metal wire layer.

According to the above object, the present invention further provides a method for manufacturing a current sensing module, the method including the following steps.

In a spacer layer manufacturing step, at least one a spacer layer includes a through hole and being annular in shape is provided.

In a structural layer manufacturing step, at least two structural layers are provided, and each of the structural layers includes an insulation layer and a metal wire layer.

In a combining step, the space layer is arranged between the two structural layers and the two insulation layers insulate the spacer layer from the two metal wire layers, the two structural layers are mutually combined to fix the spacer layer, the two metal wire layers on the two structural layers are mutually electrically connected to form a circuit board, and a loop coil for covering the spacer layer is formed by the two metal wire layers, and the circuit board is electrically connected to an external power providing a power. When the wire is located in the through hole and electrically conducted, the circuit board has a detection state in which a sensing current is outputted due to magnetic induction generated by the loop coil.

In one embodiment, the method further includes a magnetic separation layer manufacturing step, in which a magnetic separation layer is formed at an external of the circuit board and the magnetic separation layer covers the external of the circuit board.

In one embodiment, the structural layer manufacturing step further includes four of the structural layers, which are a first structural layer, a second structural layer opposite the first structural layer, a third structural layer located between the first structural layer and the second structural layer, and a fourth structural layer located between the third structural layer and the second structural layer. The spacer layer is located between the third structural layer and the fourth structural layer.

In one embodiment, the spacer layer is selected from a group consisted of a magnetic material and a non-magnetic material.

In one embodiment, the spacer layer is insulated from the first structural layer and the second structural layer.

In one embodiment, the first structural layer includes thereon a first metal wire layer, the second structural layer includes thereon a second metal wire layer mutually electrically connected to the first metal wire layer, the third structural layer includes thereon a third metal wire layer, and the fourth structural layer includes thereon a fourth metal wire layer mutually electrically connected to the third metal layer.

As described, the present invention provides following effects compared to the prior art.

1. In the manufacturing process of the circuit board of the present invention, the spacer layer is directly disposed onto the circuit board, such that insulation is directly formed between the spacer layer and the loop coil on the circuit board, thus effectively reducing the volume of the detection component and at the same time lowering material costs of the detection component.

2. The direct formation of the circuit board and the spacer layer of the present invention increases the manufacturing yield rate, allowing the present invention to be better applicable for mass production.

3. In the loop coil of the present invention, the number of turns of the loop coil is increased by increasing the number of the structural layers, thus enhancing overall magnetic field sensing amount.

4. The present invention provides the loop coil with better uniform wire distribution, which is capable of minimizing externally generated current interference during measurement process.

5. The circuit board of the present invention adopts designs in various shapes to match the shape of the detection component, and thus is able to be applied to a greater scope.

### BRIEF DESCRIPTION OF THE DRAWINGS

FIG. 1 is a schematic diagram of the present invention applied to a current sensor;

FIG. 2A is a planar schematic diagram of a current sensing module according to a first embodiment of the present invention;

FIG. 2B is an enlarged partial schematic diagram of FIG. 2A;

FIG. 3 is a sectional schematic diagram of FIG. 2B;

FIG. 4A is a planar schematic diagram of a current sensing module according to a second embodiment of the present invention;

FIG. 4B is an enlarged partial schematic diagram of FIG. 4A;

FIG. 5 is a planar schematic diagram of a current sensing module according to a third embodiment of the present invention;

FIG. 6 is a planar schematic diagram of a current sensing module according to a fourth embodiment of the present invention;

FIG. 7 is a schematic diagram of the present invention applied to another current sensor;

FIG. 8 is a planar schematic diagram of a current sensing module according to a fifth embodiment of the present invention; and

FIG. 9 is a flowchart of a manufacturing process of the present invention.

### DETAILED DESCRIPTION OF THE PREFERRED EMBODIMENTS

Details and technical contents of the present invention are given with the accompanying drawings below.

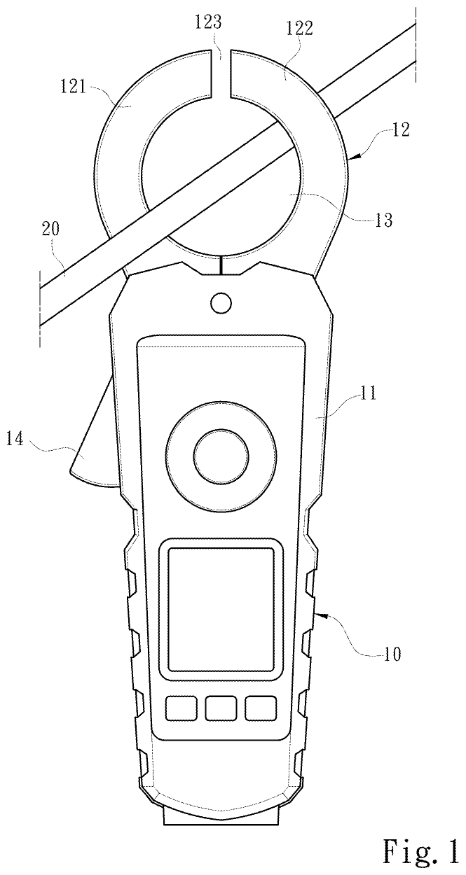

Referring to FIGS. 1, 2 and 3, as seen from the drawings, the present invention provides a current sensing module 30 adapted to be installed in a current sensor 10. The current sensor 10 includes a detection body 11 and a detection component 12 located on the detection body 11. The detection component 12 is annular in shape, and includes at least one detection hole 13 for a wire 20 to pass through. The current sensing module 30 is arranged in the detection component 12, and includes a spacer layer 40, a circuit board 50, and a magnetic separation layer 60 covering an external of the circuit board 50 and blocking between the circuit board 50 and the detection component 12.

The spacer layer 40 is made of a magnetic material or a non-magnetic material, appears as an annular shape relative to the detection component 12, and includes at a central part thereof a through hole 41 located concentrically as the detection hole 13. The magnetic material refers to a highly magnetically conductive material, and the non-magnetic material refers to a non-magnetic conductive material such as glass fiber.

The circuit board 50 is for electrically connecting to the detection body 11, and includes at least two structural layers 51 for covering the spacer layer 40. Each of the structural layers 51 includes an insulation layer 52, a metal wire layer 53 located on the insulation layer 52, and a plurality of conductive channels 59. More specifically, the plurality of conductive channels 59 include a first conductive channel 591 and a second conductive channel 592; each of the metal wire layers 53 is distributed with a plurality of conductive wires, which are not yet connected. Further, the plurality of conductive wires need to be connected on other metal wire layers 53 via other conductive channels 59. The connection of the metal wire layers 53 and the conductive channels 59 form a loop coil 54. In this embodiment, four of the structural layers 51 are used as a main implementation form, and are respectively a first structural layer 511, a second structural layer 512 opposite the first structural layer 511, a third structural layer 513 located between the first structural layer 511 and the second structural layer 512, and a fourth structural layer 514 located between the third structural layer 513 and the second structural layer 512. The spacer layer 40 is located between the third structural layer 513 and the fourth structural layer 514. Further, the first structural layer 511 includes a first insulation layer 521 and a first metal wire layer 531 located on the first insulation layer 521, the second structural layer 512 includes a second insulation layer 522 and a second metal wire layer 532 located on the second insulation layer 522, the third structural layer 513 includes a third insulation layer 523 and a third metal wire layer 533 located on the third insulation layer 523, and the fourth structural layer 514 includes a fourth insulation layer 524 and a fourth metal wire layer 534 located on the fourth insulation layer 524. The first metal wire layer 531 is mutually electrically connected to the second metal wire layer 532 via the first conductive channel 591, and the third metal wire layer 533 is mutually electrically connected to the fourth metal wire layer 534 via the second conductive channel 592, such that the first metal wire layer 531, the second metal wire layer 532, the third metal wire layer 533 and the fourth metal wire layer 534 form the loop coil 54, surround an external of the spacer layer 40, and are mutually insulated from the spacer layer 40 through the first insulation layer 521, the second insulation layer 522, the third insulation layer 523 and the fourth insulation layer 524. The circuit board 50 further includes a first electrode contact 55 and a second electrode contact 56, wherein the first electrode contact 55 and the second electrode contact 56 are mutually electrically connected to the metal wire layer 53 and the detection body 11, respectively.

Accordingly, when the wire 20 is inserted in the detection hole 13 and a current passes through the wire 20, the loop coil 54 formed by the first metal wire layer 531, the second metal wire layer 532, the third metal wire layer 533 and the fourth metal wire layer 534 on the circuit board 50 generates magnetic induction due to the current passing through the wire 20, and hence a sensing current is generated. The sensing current is transmitted to the detection body 11, which then provides the current value at the present time according to the sensing current. In an implementation of the embodiment, when the spacer layer 40 is the magnetic material, a smaller current is detected, wherein the detected current value has a higher resolution. When the spacer layer 40 is a non-magnetic material, a larger current is detected.

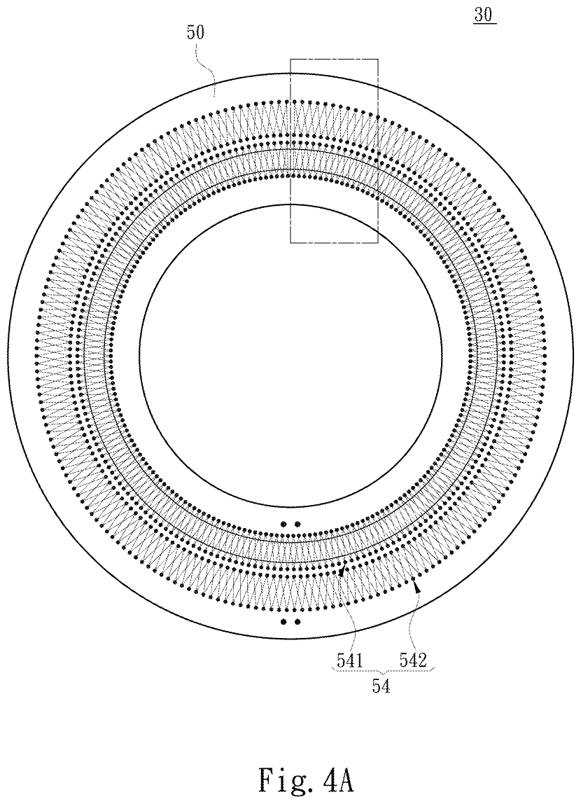

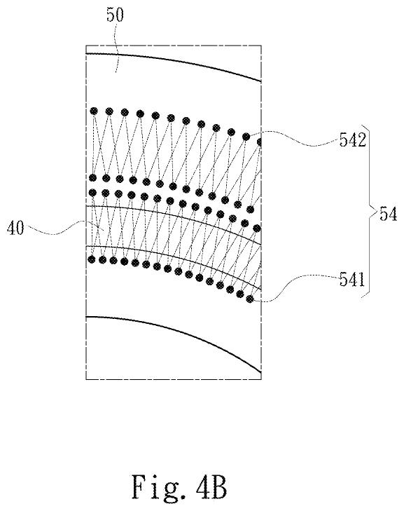

Again referring to FIGS. 1, 4A and 4B, in one embodiment, the circuit board 50 is further provided with two of the loop coils 54, including a first loop coil 541 and a second loop coil 542 provided around an external of the first loop coil 541. In this embodiment, the spacer layer 40 is provided in the first loop coil 541, and no spacer layer 40 is provided in the second loop coil 542. The first loop coil 541 and the second loop coil 542 are mutually electrically connected to the detection body 11 via the circuit board 50, respectively.

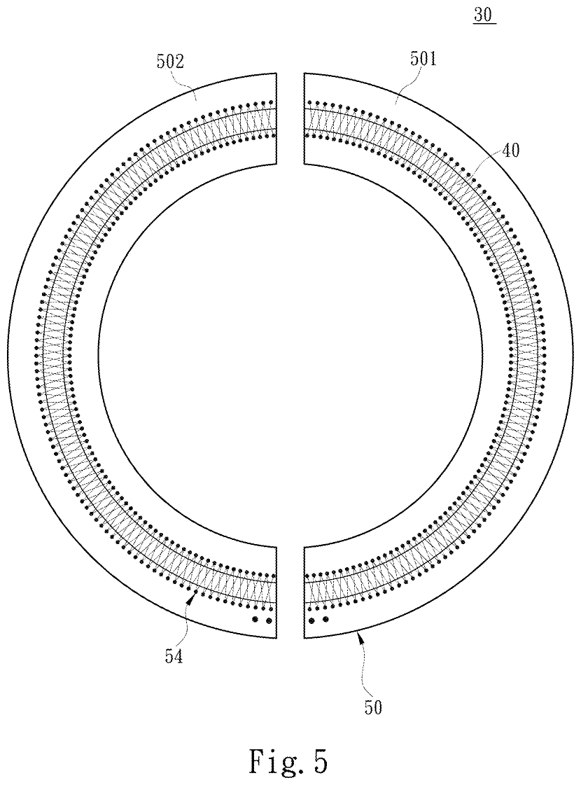

Again referring to FIGS. 1, 5 and 6, in one embodiment, a pressing component 14 linked with the detection component 12 is further provided at an external of the detection body 11, the detection component 12 includes a first annular portion 121 and a second annular portion 122, and at least one disconnected portion 123 is formed at an adjacent position of the first annular portion 121 and the second annular portion 122. When the pressing component 14 on the detection body 11 is pressed, the distance of the disconnected portion 123 between the first annular portion 121 and the second annular portion 122 is increased, allowing the wire 20 to pass through the disconnected portion 123 to enter the detection hole 13. The circuit board 50 includes a first circuit board 501 corresponding to the first annular portion 121 and a second circuit board 502 corresponding to the second annular portion 122. The first circuit board 501 and the second circuit board 502 are semi-annular in shape. The loop coil 54 is disposed on each of the first circuit board 501 and the second circuit board 502, and the spacer layer 40 is covered by each of the loop coils 54.

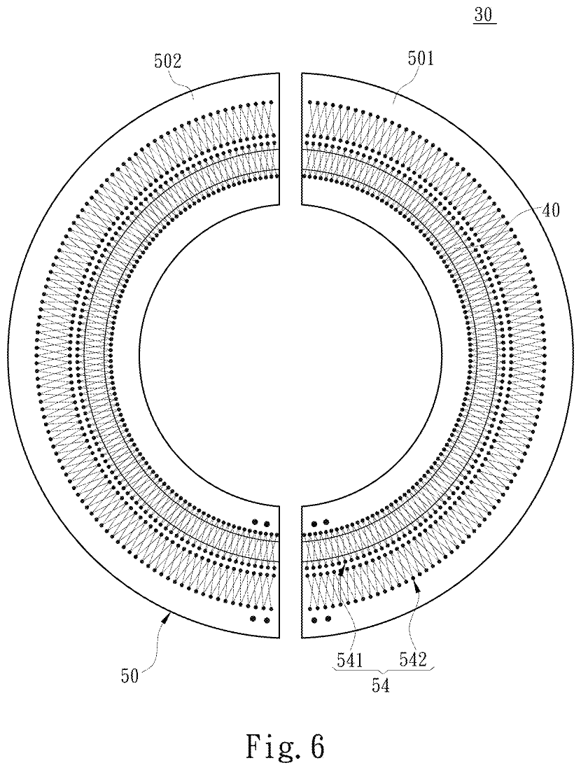

In one embodiment, as shown in FIG. 6, the first loop coil 541 and the second loop coil 542 are respectively formed on the first circuit board 501 and the second circuit board 502, and the spacer layer 40 is provided in the first loop coil 541 but not provided in the second loop coil 542. In this embodiment, the first loop coil 541 and the second loop coil 542 are shaped correspondingly to the shapes of the first annular portion 121 and the second annular portion 122, and are both semi-annular.

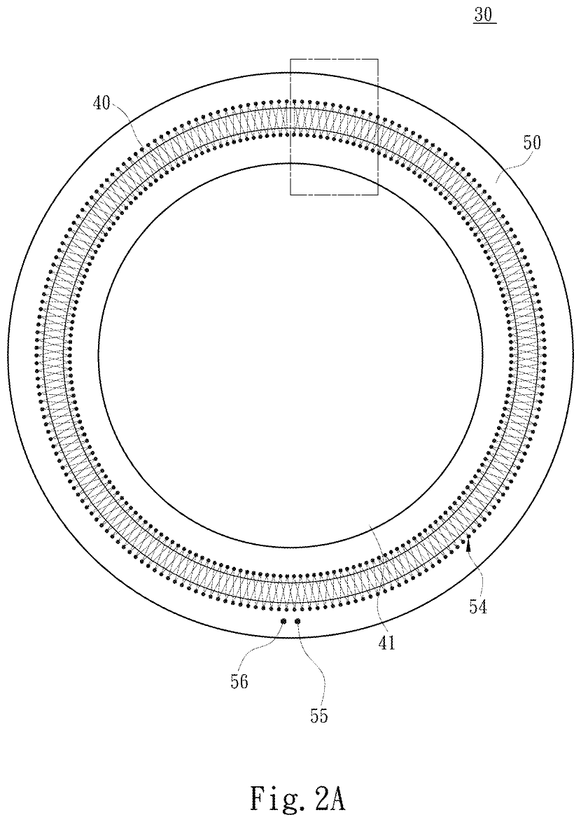

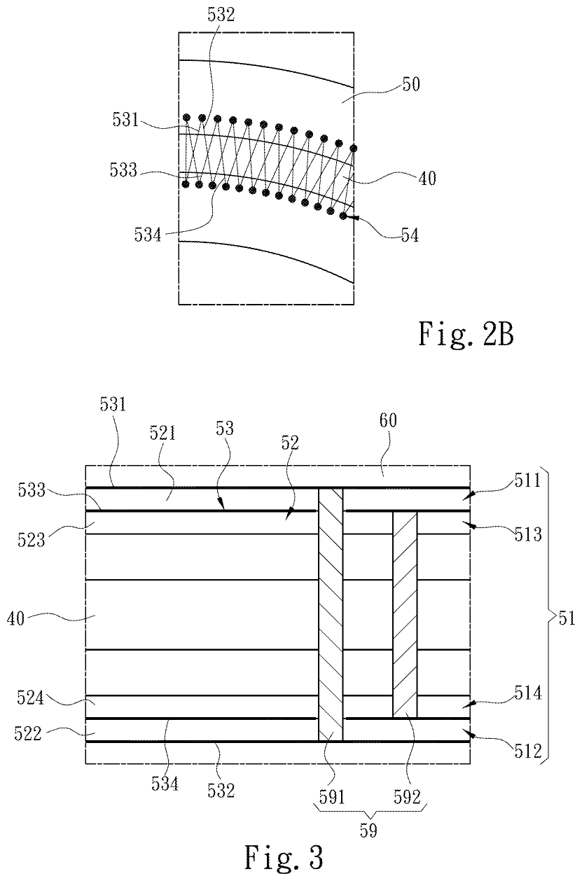

In other words, the loop coil 54 of the circuit board 50 of the present invention may be in an enclosed annular shape as shown in FIG. 2A, or in a non-enclosed annular shape as shown in FIG. 6. When the loop coil 54 is in the enclosed annular shape, optimization for reducing outer peripheral current interference is minimized. When the loop coil 54 is in the non-enclosed annular shape, the density of the loop coil 54 at disconnected parts is increased to compensate non-uniformity generated by the discontinuity at the disconnected parts of the loop coil 54, similarly reducing the outer peripheral current interference.

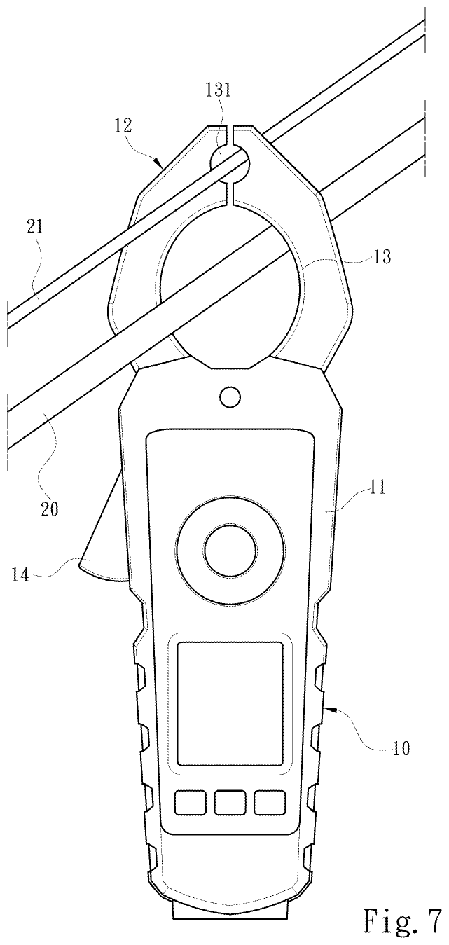

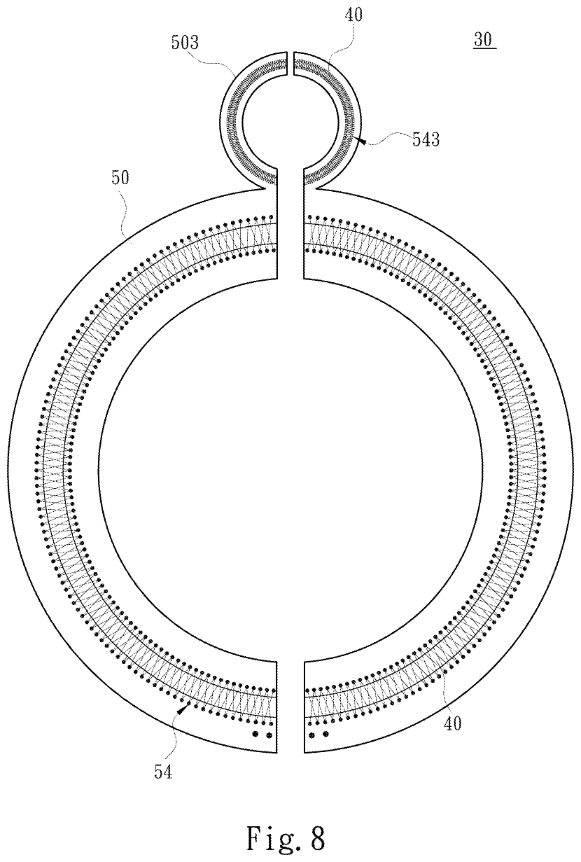

Again referring to FIGS. 7 and 8, in one embodiment, the detection component 12 further includes a first detection hole 131, which is spaced from the detection hole 13. An aperture of the first detection hole 131 is smaller than an aperture of the detection hole 13, so as to allow the wire 20 and a first wire 21 having a line width smaller than that of the wire 20 to respectively pass through the detection hole 13 and the first detection hole 131. And the detection hole 13 and the first detection hole 131 detect current values of the wire 20 and the first wire 21, respectively.

In this embodiment, as shown in FIGS. 7 and 8, an extension circuit board 503 is for fried at a position of the circuit board 50 corresponding to the first detection hole 131. The extension circuit board 503 is mutually electrically connected to the circuit board 50, and is provided thereon with a third loop coil 543, wherein the spacer layer 40 is provided in the third loop coil 543. Accordingly, with the loop coil 54 provided on the circuit board 50 correspondingly to the detection hole 13 and the extension circuit board 503 provided correspondingly to the first detection hole 131, the current values of the wire 20 and the first wire 21 is detected respectively through the detection hole 13 and the first detection hole 131.

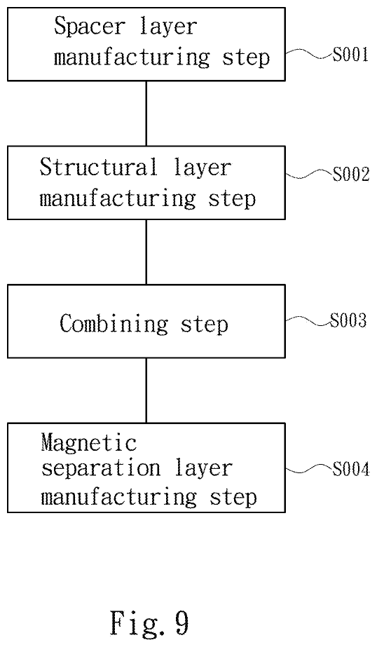

Again referring to FIGS. 1, 2A, 2B, 3 and 9, the present invention further provides a current sensing module manufacturing method for manufacturing the current sensing module 30. The current sensing module manufacturing method includes a spacer layer manufacturing step S001, a structural layer manufacturing step S002, a combining step S003 and a magnetic separation layer step S004.

In the spacer layer manufacturing step S001, a magnetic material or a non-magnetic material is primarily used to manufacture the annular-shaped spacer layer 40, and the through hole 41 is formed on the spacer layer 40.

In the structural layer manufacturing step S002, at least two of structural layers 51 for covering the spacer layer 40 are provided. Each of the structural layers 51 includes the metal wire layer 53 formed on the insulation layer 52 via electroplating, coating or printing.

In the combining step S003, the spacer layer 40 is provided between the two structural layers 51 so as to the two insulation layers 52 insulate the spacer layer 40 from the two metal wire layers 53. The two insulation layers 52 of the two structural layers 51 are mutually combined through adhesion or pressing to fix the spacer layer 40, two of metal wire layers 53 on the two structural layers 51 are mutually electrically connected to form the circuit board 50, and the loop coil 54 for covering the spacer layer 40 is formed by the two metal wire layers 53 and the conductive channels 59. When the wire 20 is located in the through hole 41, the circuit board 50 has a detection state in which a sensing current is outputted due to magnetic induction generated by the loop coil 54 when the wire 20 is electrically conducted.

In the magnetic separation layer manufacturing step S004, a magnetic separation layer 60 is formed at the external of the circuit board 50 and the magnetic separation layer 60 covers the external of the circuit board 50, thereby the circuit board 50 blocked from the detection component 12 by the magnetic separation layer 60 therebetween.

It should be noted that, during a manufacturing process of the circuit board 50, the spacer layer 40 of the present invention is arranged between the two structural layers 51 via a pressing process of the two structural layers 51. Further, the two insulation layers 52 of the two structural layers 51 are connected through hot-pressing or adhesion such that the two metal wire layers 53 are insulated from the spacer layer 40 through the two insulation layers 52 Next, using a manufacturing step in the manufacturing process of the circuit board 50, such as drilling, exposure, etching, electroplating, cleaning, applying or printing, the two metal wire layers 53 are electrically connected to form the loop coil 54, allowing the loop coil 54 to surrounded the spacer layer 40 and thus completing the manufacturing of the current sensing module 30.

Thus, not only the volume of the current sensing module 30 is reduced but also the manufacturing yield rate is increased, making the present invention be better applicable for mass production. Further, the number of turns of the loop coil 54 is able to be increased by increasing the number of the structural layers 51, and the circuit board 50 is manufactured by a multi-layer circuit board process, thus further enhancing a magnetic field sensing amount of the detection body 11. Further, the circuit board 50 provides the loop coil 54 with more uniform wire distribution, such that current interference generated by an external environment is minimized during measurement process. Moreover, the circuit board 50 adopts designs of various shapes to match the shape of the detection component 12, and thus is applied to a greater scope.

What is claimed is:

1. A current sensing module for a current sensor, the current sensing module comprising:
at least one spacer layer, being annular in shape, including a through hole at a center thereof for a wire to pass through; and
at least one circuit board, electrically connected to the current sensor, the circuit board including at least two structural layers for covering the spacer layer, each of the structural layers comprising an insulation layer and a metal wire layer located on the insulation layer and insulated from the spacer layer, the two metal wire layers mutually electrically connected to form at least one loop coil, the loop coil surrounding the spacer layer;
wherein when the wire is located in the through hole and electrically conducted, the circuit board has a detection state in which a sensing current is outputted due to magnetic induction generated by the loop coil.

2. The current sensing module for a current sensor of claim 1, further comprising a magnetic separation layer for covering an external of the circuit board.

3. The current sensing module for a current sensor of claim 2, wherein the circuit board further comprises four of the structural layers, which are a first structural layer, a second structural layer opposite the first structural layer, a third structural layer located between the first structural layer and the second structural layer, and a fourth structural layer located between the third structural layer and the second structural layer; the spacer layer is located between the third structural layer and the fourth structural layer.

4. The current sensing module for a current sensor of claim 3, wherein the spacer layer is selected from a group consisted of a magnetic material and a non-magnetic material.

5. The current sensing module for a current sensor of claim 4, wherein the spacer layer is insulated from the first structural layer and the second structural layer.

6. The current sensing module for a current sensor of claim 3, wherein the first structural layer includes thereon a first metal wire layer, the second structural layer includes thereon a second metal wire layer mutually electrically connected to the first metal wire layer, the third structural layer includes thereon a third metal wire layer, and the fourth structural layer includes thereon a fourth metal wire layer mutually electrically connected to the third metal wire layer.

7. A method for manufacturing a current sensing module, comprising steps of:
a spacer layer manufacturing step: providing at least one spacer layer including a through hole and being annular in shape;
a structural layer manufacturing step: providing at least two structural layers, each of the structural layers comprising an insulation layer and a metal wire layer; and
a combining step: arranging the spacer layer between the two structural layers to insulate the spacer layer from the two metal wire layers through the two insulation layers, mutually combining the two structural layers to fix the spacer layer, mutually electrically connecting the two metal wire layers on the two structural layers to form a circuit board, and the two metal wire layers forming a loop coil for covering the spacer layer;
wherein when a wire is located in the through hole and electrically conducted, the circuit board has a detection state in which a sensing current is outputted due to magnetic induction generated by the loop coil.

8. The method for manufacturing a current sensing module of claim 7, further comprising a step of:
forming a magnetic separation layer at an external of the circuit board and the magnetic separation layer covering the external of the circuit board.

9. The method for manufacturing a current sensing module of claim 8, wherein the structural layer manufacturing step further comprises four of the structural layers, which are a first structural layer, a second structural layer opposite the first structural layer, a third structural layer located between the first structural layer and the second structural layer, and a fourth structural layer located between the third structural layer and the second structural layer; wherein the spacer layer is located between the third structural layer and the fourth structural layer.

10. The method for manufacturing a current sensing module of claim 9, wherein the spacer layer is selected from a group consisted of a magnetic material and a non-magnetic material.

11. The method for manufacturing a current sensing module of claim 10, wherein the spacer layer is insulated from the first structural layer and the second structural layer.

12. The method for manufacturing a current sensing module of claim 9, wherein the first structural layer includes thereon a first metal wire layer, the second structural layer includes thereon a second metal wire layer mutually electrically connected to the first metal wire layer, the third structural layer includes thereon a third metal wire layer, and the fourth structural layer includes thereon a fourth metal wire layer mutually electrically connected to the third metal wire layer.
